(19) United States
(12) Patent Application Publication
(10) Pub. No.: US 2011/0100554 A1
(43) Pub. Date: May 5, 2011

(54) PARALLEL SYSTEM FOR EPITAXIAL CHEMICAL VAPOR DEPOSITION

(75) Inventors: DAVID K. CARLSON, San Jose, CA (US); ERROL ANTONIO C. SANCHEZ, Tracy, CA (US); HERMAN P. DINIZ, Fremont, CA (US)

(73) Assignee: APPLIED MATERIALS, INC., Santa Clara, CA (US)

(21) Appl. No.: 12/876,563

(22) Filed: Sep. 7, 2010

Related U.S. Application Data
(60) Provisional application No. 61/241,002, filed on Sep. 9, 2009.

(51) Int. Cl. H01L 21/465

(52) U.S. Cl. 156/345.29; 118/719; 257/E21.485

(57) ABSTRACT

Embodiments of a parallel system for epitaxial deposition are disclosed herein. In some embodiments, a parallel system for epitaxial deposition includes a first body having a first process chamber and a second process chamber disposed within the first body; a shared gas injection system coupled to each of the first and the second process chambers; and a shared exhaust system coupled to each of the first and second process chambers, the exhaust system having independent control of an exhaust pressure from each chamber. In some embodiments, the gas injection system provides independent control of flow rate of a gas entering each chamber.

### CROSS-REFERENCE TO RELATED APPLICATIONS

This application claims benefit of U.S. provisional patent application Ser. No. 61/241,002, filed Sep. 9, 2009, which is herein incorporated by reference in its entirety.

### FIELD

Embodiments of the present invention generally relate to semiconductor processing equipment.

### BACKGROUND

In semiconductor processing equipment, one exemplary manner for improving wafer throughput may be through the use of multiple process chambers. In some systems, such process chambers may be disposed on a common platform and may share certain resources. Unfortunately, the inventors have discovered that conventional systems may be inadequate for some semiconductor processes, such as, for example, epitaxial growth processes, due to inadequate control over shared resources at each process chamber.

### SUMMARY

Embodiments of a parallel system for epitaxial deposition are disclosed herein. In some embodiments, a parallel system for epitaxial deposition includes a first body having a first process chamber and a second process chamber disposed within the first body; a shared gas injection system coupled to each of the first and second process chambers; and a shared exhaust system coupled to each of the first and second process chambers, the exhaust system having independent control of exhaust pressure from each chamber. In some embodiments, the gas injection system provides independent control of flow rate of a gas entering each chamber.

In some embodiments, the exhaust system includes an exhaust pump coupled to the first and second process chambers; a first ballast system coupled to the first process chamber to independently control exhaust pressure from the first process chamber; and a second ballast system coupled to the second process chamber to independently control exhaust pressure from the second process chamber. In some embodiments, the each ballast system includes a ballast supply coupled to the process chamber via a mass flow controller to provide a ballast gas to adjust the pressure in each chamber; and a pressure transducer coupled to each chamber to monitor the pressure in each chamber.

In some embodiments, the gas injection system includes a deposition system coupled to the first and second process chambers; an etch system coupled to the first and second process chambers; and a vent system coupled to the deposition system and the etch system to selectively vent gases from each of the deposition and etch systems.

In some embodiments, the deposition system includes a deposition manifold a deposition manifold for providing a deposition gas; a first deposition flow controller disposed between the deposition manifold and the first process chamber to independently control the flow rate of the deposition gas entering the first process chamber; and a second deposition flow controller disposed between the deposition manifold and the second process chamber to independently control the flow rate of the deposition gas entering the second process chamber.

In some embodiments, the etch system includes an etch manifold for providing an etch gas; a first etch flow controller disposed between the etch manifold and the first process chamber to independently control the flow rate of the etch gas entering the first process chamber; and a second etch flow controller disposed between the etch manifold and the second process chamber to independently control the flow rate of the etch gas entering the second process chamber.

In some embodiments, the vent system includes a vent manifold to vent gases from the etch and deposition systems; a first backpressure regulator disposed between the vent manifold and the deposition manifold to selectively permit gases from the deposition system to enter the vent system; and a second backpressure regulator disposed between the vent manifold and the etch manifold to selectively permit gases from the etch system to enter the vent system.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of a processing system in accordance with some embodiments of the present invention.

FIG. 2 is a schematic top view of a processing system illustrated in FIG. 1.

FIG. 3 is a schematic view of an exhaust system of a processing system in accordance with some embodiments of the present invention.

FIG. 4 is a schematic view of an gas injection system of a processing system in accordance with some embodiments of the present invention.

To facilitate understanding, identical reference numerals have been used, where possible, to designate identical elements that are common to the figures. The above drawings are not to scale and may be simplified for illustrative purposes.

### DETAILED DESCRIPTION

Embodiments of a parallel system for epitaxial deposition are provided herein. The parallel system described herein advantageously may provide improved processing and process throughput for epitaxial growth processes at cost reduction through utilizing shared system resources (e.g., exhaust and gas injection systems) having independent control at each process chamber.

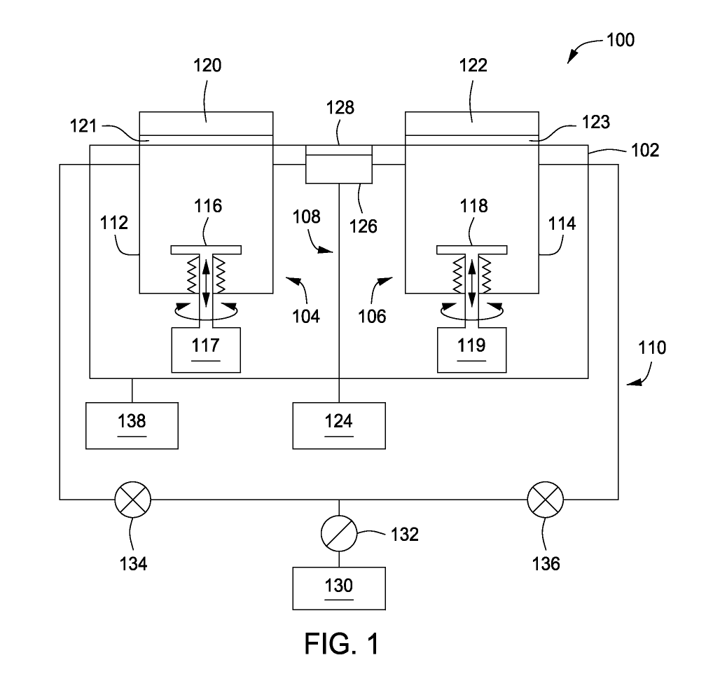

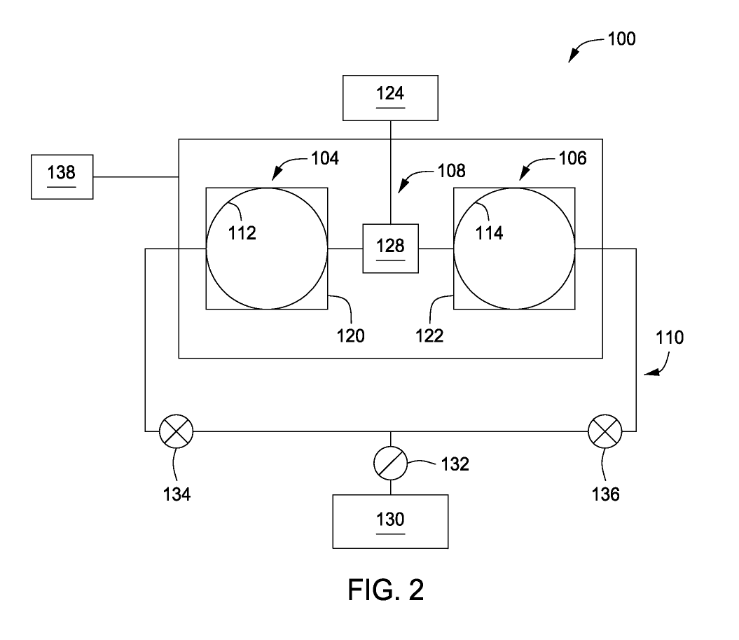

FIGS. 1-2 respectively depict a schematic side view and top view of a parallel system 100 in accordance with some embodiments of the present invention. The parallel system for epitaxial deposition described herein may include a common platform (e.g., a first body) having a plurality of process chambers disposed therein. In one illustrative and non-limiting example depicted in FIG. 1, the parallel system 100 may include two process chambers (e.g., a first process chamber 104 and a second process chamber 106) disposed in a first body 102. A shared gas injection system 108 may be coupled to the first and second process chambers 104, 106 for providing a process gas to each chamber. A shared exhaust system 110 may be coupled to the first and second process chambers 104, 106 for controlling exhaust pressure from each chamber.

The first body 102 may include a hollow shell formed of a plastic or other suitable material such as stainless steel or aluminum. In some embodiments, the hollow shell may be filled with an epoxy which surrounds the first and second process chamber 104 and 106. In some embodiments, the epoxy may be a thermally conductive, electrically insulating epoxy designed for heat sinking and encapsulation, such as EPO-TEK® T905BN-3, available from Epoxy Technology, Inc. of Billerica, Mass. The epoxy may provide rigidity and thermal stability to the parallel system 100. In some embodiments, the hollow shell used in forming the general shape of the first body 102 may be removed, thus the first body 102 may comprise only the formed epoxy. The first body 102 may include access ports (not shown) formed during filling process. Access ports may be included, for example, to allow access to components of the parallel system 100 such as the gas injection system 108, the exhaust system 110, or other components of each process chamber such as lift mechanisms for substrate supports, cooling tubes, gas inlets and gas outlets, and other system components described below.

The first and second process chambers 104, 106 are disposed within the first body 102. The first and second process chambers 104, 106 may be substantially equivalent in size and shape, and having substantially equivalent components, such as substrate support, lift mechanism, lamp heating system, and the like, coupled thereto.

The first process chamber 104 includes a chamber body 112 having a substrate support 116 disposed therein and a heating system 120 coupled thereto. The chamber body 112 may be formed of stainless steel tubing, for example 316 stainless steel or other suitable grades of stainless steel or other materials compatible with epitaxial deposition processes. The inner surface of the chamber body 112 may be lined and/or coated with a material suitably resistant to corrosion by process gases typically used in epitaxial deposition processes. Examples of suitable materials include 316L Stainless Steel electropolished to 5-10 Ra, high nickel content alloys (e.g., HASTELLOY®), NEDOX®, or the like. In some embodiments, the chamber body 112 may be surrounded by tubing (not shown) for facilitating the flow of water or other suitable cooling fluids therethrough. The tubing may comprise brazed copper or another suitable material for facilitating heat transfer between the chamber body 112 and the cooling fluids.

The substrate support 116 may be any substrate support suitable for epitaxial deposition processes. The substrate support may include a means for securing a substrate disposed thereon such as an electrostatic chuck, vacuum chuck, and/or guide pins disposed peripherally around the circumference of the support surface. The substrate support 116 may include a mechanism 117 for raising and lowering the substrate support 116 along a central axis of the chamber body 112. The substrate support may be raised or lowered, for example, to interface with a slit valve (not shown) for inserting or removing a substrate from the chamber body 112, or for adjusting the proximity of the substrate relative to a chamber component, for example, the heating system 120. The mechanism 117 may be further capable of rotating the substrate support 116 about the central axis. Rotation of the substrate support 116 may be desirable, for example, during a deposition process to provide a uniform distribution of process gas across the substrate surface.

The heating system 120 may be configured as necessary for providing energy to heat the inner volume of the chamber body 112 or a substrate being processed therein, or to induce a chemical reaction in process gases being used to deposit an epitaxial layer on a substrate being processed. The heating system 120 may be any suitable system for providing energy, such as a radiant heating system, for example, a lamp heating system that uses a plurality of lamps to provide energy to the processing system. In some embodiments, one or more reflectors (not shown) may be disposed in the inner volume of the chamber body 112, and positioned as necessary to direct radiation from the heating system 120 to the substrate surface.

In one non-limiting embodiment, the heating system 120 may be disposed above the first process chamber 104, as illustrated in FIGS. 1-2. The heating system 120 may be coupled to the chamber body 112 via a flange 121, for example fabricated from steel, and separated from an inner volume of the chamber body 112 via a transparent window (not shown). The transparent window may comprise any suitable material that is transparent to the wavelength of radiation provided by the heating system 120 and chemically compatible with the process gases used in epitaxial deposition processes. In some embodiments, the transparent window may be quartz. Alternatively or in combination, the heating system 120, or portions thereof, may be disposed below the chamber body 112. Thus, the heating system may be disposed above, below, or both above and below the chamber body 112. In some embodiments, the heating system may include supplemental heating sources for providing at least one of ultraviolet (UV) or infrared (IR) energy.

The second process chamber 106 may be substantially equivalent to the first process chamber 104 and may have substantially equivalent chamber components and embodiments thereof as described above. In some embodiments, and as depicted in FIGS. 1-2, the second process chamber includes a chamber body 114, a substrate support 118 coupled to a lift/rotation mechanism 119, and a heating system 122 disposed above the chamber body 114. Similar to the first process chamber 104, the heating system 122 is coupled to the chamber body 114 via a flange 123. Other embodiments of the heating system 122 are possible, as discussed above regarding heating system 120.

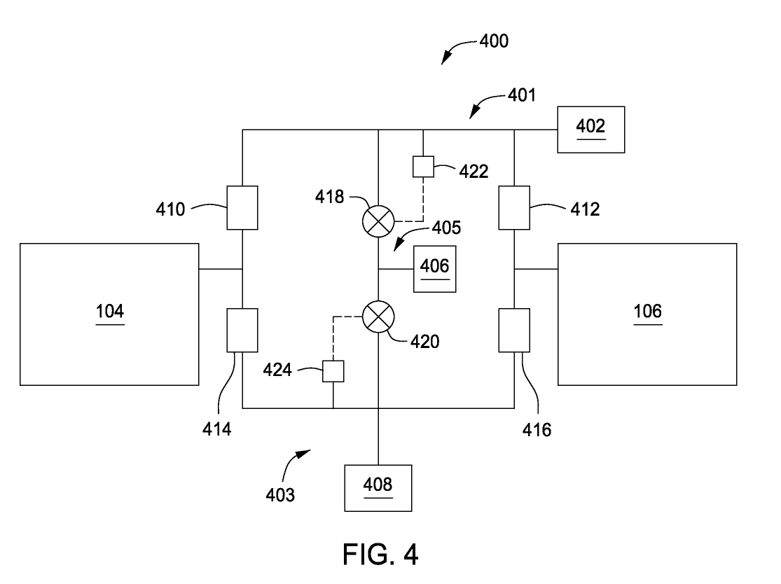

The parallel system 100 further includes a shared gas injection system 108 coupled to the first and second process chambers 104, 106. In some embodiments, and as depicted in FIGS. 1-2, the gas injection system 108 may include a process manifold 124 and an inlet assembly 126. The process manifold may include one or more manifolds for introducing or regulating the flow of process gases, and is discussed further below with respect to FIG. 4. The inlet assembly 126 may include a transparent window 128 to facilitate providing energy for activating process gases prior to entering the first or second process chambers 104, 106. The energy may be provided from a light source or by any suitable means for activating a process gas. Specifically, the inlet assembly 126 may be disposed, for example, between a manifold supplying a process gas (or process gas mixture) and mass flow controllers which independently control the flow rate of the process gas (or process gas mixture) entering each process chamber 104, 106 of the parallel system 100. The manifold and mass flow controllers are discussed further below with respect to the gas injection system 400 in FIG. 4.

The parallel system 100 further includes a shared exhaust system 110 coupled to the first and second process chambers 104, 106. In some embodiments, and as depicted in FIGS. 1-2, the exhaust system 110 includes an exhaust pump 130 coupled to the first and second chambers 104, 106 via a pressure control valve 132. The pressure control valve 132 may be used to coarsely and simultaneously regulate the exhaust pressure in the first and second process chambers 104, 106. The pressure control valve 132 does not provide independent control of the exhaust pressure in each process chamber.

The exhaust system 110 may include a first isolation valve 134 disposed between the first process chamber 104 and the pressure control valve 132 and a second isolation valve 136 disposed between the second process chamber 106 and the pressure control valve 132. The first isolation valve 134 may close the first process chamber 104 to the exhaust pump 130, for example, when it is desired to run epitaxial deposition processes in only the second process chamber 106. Likewise, the second isolation valve 136 closes the second process chamber to the exhaust pump 130. Optionally, a variable speed blower (not shown) may be disposed between the pressure control valve 132 and the exhaust pump 130. The variable speed blower can be utilized to increase the flow capacity of the pump, and/or may be utilized to optimize the pumping capacity to improve the response characteristics of the pressure control valve 132.

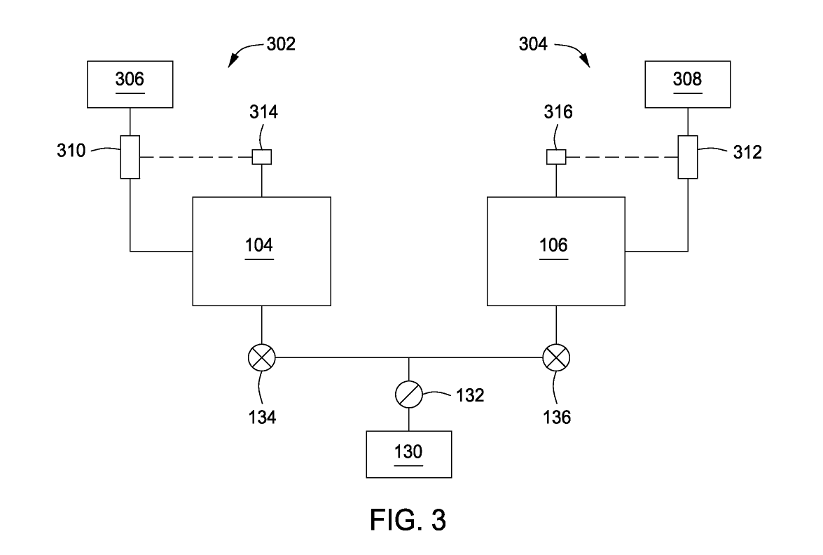

The exhaust system 110 may provide for independent control of the pressure in each process chamber. For example, referring to FIG. 3, the exhaust system 110 may include a first ballast system 302 coupled to the first process chamber 104 and a second ballast system 304 coupled to the second process chamber 106. The first and second ballast systems 302, 304 may be used to independently control the exhaust pressure in the first and second process chambers 104, 106, respectively. Each ballast system may be utilized to modify exhaust pressure in each chamber independently and advantageously may be utilized without affecting the partial pressure of a process gas entering each process chamber from the gas injection system.

The first ballast system 302 includes a first ballast supply 306 coupled to the first process chamber 104 via a first mass flow controller 310. A first pressure transducer 314 may be coupled to the first process chamber 104 to monitor the exhaust pressure in the first process chamber 104. The first ballast supply 306 may supply a ballast gas to the first process chamber 104. The ballast gas may be a gas that is inert to the process being performed in the process chamber to minimize the impact of providing the ballast gas during processing. In some embodiments, the ballast gas may include at least one of nitrogen (N₂) or hydrogen (H₂). A flow rate of the ballast gas entering the first process chamber 104 may be controlled by the first mass flow controller 310. In operation, the first mass flow controller 310 and first pressure transducer 314 may function as part of a closed feedback loop to facilitate maintaining the exhaust pressure at a desired setpoint pressure in the first process chamber 104. For example, if the first pressure transducer 314 measures an exhaust pressure below the desired setpoint pressure, the flow rate of a ballast gas provided by the first ballast supply 306, and controlled by the first mass flow controller 310, may be increased. In some embodiments, when the exhaust pressure exceeds the desired setpoint pressure, the flow rate of the ballast gas may be decreased.

The second ballast system 304 may be substantially equivalent in both composition and function to the first ballast system 302 as described above. The second ballast system 304 is coupled to the second process chamber 106, and independently regulates the exhaust pressure therein. The second ballast system 304 may include a second ballast supply 308 coupled to the second process chamber 106 via a second mass flow controller 312, and a second pressure transducer 316 to monitor exhaust pressure in the second process chamber 106. The second ballast supply 308 may provide one or more of the ballast gases described above to the second process chamber 106. In operation, the second mass flow controller 310 and second pressure transducer 314 may function as part of a closed feedback loop for the purposes of maintaining exhaust pressure at a desired setpoint pressure in the second process chamber 106. The first and second ballast systems 302, 304 can be utilized to independently fine tune the pressure balance in each process chamber, for example, to eliminate pressure variants between the two chambers. The first and second ballast systems 302, 304 can be also be utilized to eliminate crosstalk between the two process chambers such that changes in pressure in one chamber will not affect the pressure in the other chamber.

One exemplary and non-limiting example of a gas injection system that may be used in the parallel system 100 is depicted in FIG. 4. The gas injection system 400 is coupled to the first and second process chambers 104, 106, and may be utilized for independently controlling and maintaining the flow rate of process gases (or process gas mixtures) at each process chamber 104, 106. In some embodiments, the gas injection system 400 may include a deposition system 401, an etch system 403, and a vent system 405.

The deposition system 401 is configured for providing one or more deposition gases to the process chamber. The deposition system 401 may include a deposition manifold 402, a first deposition mass flow controller 410, and a second deposition mass flow controller 412. The first and second deposition mass flow controllers 410, 412 couple the deposition manifold 402 to the first and second process chambers 104, 106 respectively. The first and second deposition mass flow controllers 410, 412 facilitate independent control of the flow rate of a deposition gas at the first and second process chambers 104, 106 respectively.

The deposition manifold 402 may include one or more deposition gas sources (not shown) and one or more mass flow controllers (not shown) for controlling a flow rate of one or more deposition gases from the one or more gas sources. The one or more deposition gases may include gases that contribute the primary materials to be deposited on a substrate. In a non-limiting example, the one or more deposition gases may include at least one of dichlorosilane (SiH₂Cl₂), silane (SiH₄), disilane (Si₂H₆), germane (GeH₄), higher order silanes or germanes, group III/V compounds or dielectrics, or the like. The one or more deposition gases may also include gases that contribute one or more dopant elements that may be combined with the primary materials to be deposited on a substrate. Non-limiting examples of such gases may include phosphine (PH₃), arsine (AsH₃), and the like.

The deposition gases may be mixed in the deposition manifold forming a deposition gas mixture that may be provided to the first and second process chambers 104, 106 independently via the first and second deposition mass flow controllers 410, 412. For example, a composition of the deposition gas mixture provided by the deposition manifold 402 to the first and second process chambers 104, 106 may be the same. In some embodiments, the flow rate of the deposition gas mixture at each process chamber may be varied via the first or second deposition mass flow controller 410, 412 in accordance with processing conditions in each process chamber. Although described in terms of a single deposition manifold 402, multiple deposition manifolds and/or multiple deposition sources coupled to a single deposition manifold may be provided. For example, separate silicon and germanium sources or separate Group III and Group V sources may be provided and coupled to a single deposition manifold or to independent deposition manifolds.

The etch system 403 is configured for providing one or more etch gases to the process chamber. The etch system 403 may include an etch manifold 408, a first etch mass flow controller 414, and a second etch mass flow controller 416. The first and second etch mass flow controllers 414, 416 couple the etch manifold 408 to the first and second process chambers 104, 106 respectively. The first and second etch mass flow controllers 414, 416 facilitate independent control of the flow rate of a etch gas at the first and second process chambers 104, 106 respectively.

The etch manifold 408 may include one or more etch gas sources (not shown) and one or more mass flow controllers (not shown) for controlling a flow rate of one or more etch gases from the one or more gas sources. In a non-limiting example, the one or more etch gases may include at least one of chlorine (CL₂), hydrogen chloride (HCl), nitrogen trifluoride (NF₃), carbon tetrafluoride (CF₃), or the like. The etch gases may be mixed in the deposition manifold forming an etch gas mixture that may be provided to the first and second process chambers 104, 106 independently via the first and second etch mass flow controllers 414, 416. For example, a composition of the etch gas mixture provided by the etch manifold 408 to the first and second process chambers 104, 106 may be the same. In some embodiments, the flow rate of the etch gas mixture at each process chamber may be varied via the first or second etch mass flow controller 414, 416 in accordance with processing conditions in each process chamber.

The vent system 405 may be coupled to the deposition system 401 and the etch system 403. The vent system 405 may include a vent manifold 406, a first backpressure regulator 418, and a second backpressure regulator 420. The first backpressure regulator 418 may be disposed between the vent manifold and the deposition manifold, and second backpressure regulator 420 may be disposed between the vent manifold and the etch manifold.

The vent manifold 406 may include a pump (not shown) or other suitable means for providing a first region of reduced pressure, wherein the reduced pressure may be less than a pressure in the deposition system 401 or the etch system 403. The vent manifold 406 may be utilized as a means to regulate pressure in the deposition system 401 and etch system 403. For example, epitaxial deposition processes may require rapid introduction of a gas into each process chamber. Thus, deposition and etch gases may be flowing continuously from the deposition manifold 402 and the etch manifold 408, even when the deposition system 401 or etch system 403 is closed to each process chamber. Such continuous flow can create pressure build up in the deposition system 401 and etch system 403 when the respective system is closed to either or both process chambers. Such pressure build up may be relieved when the respective isolation valves are opened. However, such pressure fluctuations may undesirably lead to unacceptable process variation. In addition, if unchecked, the pressure build up in each system may result in a leak, rupture, or the like. Thus, the vent manifold 408 may prevent such pressure build up and may provide more uniform pressure during the cycling of coupling the respective etch and deposition systems to the process chambers.

When the deposition system 401, the etch system 403, or both are open to either or both of the process chambers 104, 106, a pressure drop may result. The pressure drop may be causes by, for example, a high flow rate of a gas (or gas mixture) being introduced into each process chamber. The pressure drop may result in one or more second regions of low pressure in the deposition system 401 or etch system 403 that is less that of the first region in the vent system 405. Under such conditions, gases in the first region may back stream into the deposition system 401 or the etch system 403, leading to contamination, undesired gases or compositions of gases, and generally reducing process performance. The first and second back pressure regulators 418, 422 may be utilized to prevent such back streaming of vent gases.

For example, in the deposition system 401, the first back pressure regulator 418 and a pressure transducer 422 may function as part of a closed feedback loop for the purposes of maintaining a pressure at a desired setpoint pressure (e.g., greater than pressure in the vent manifold 408) in the deposition system 401. The pressure transducer 422 may be coupled to the deposition system 401 for monitoring the pressure therein. If the pressure transducer 422 measures a pressure below the desired setpoint pressure, the first back pressure regulator 418 may close, and re-open once the pressure in the deposition system 401 has been restored to the desired setpoint pressure (e.g., greater than pressure in the vent manifold 408).

A substantially equivalent closed feedback loop may be present in the etch system 403. Here, the second pressure regulator 420 and a pressure transducer 424 may function as part of a closed feedback loop to regulate pressure in the etch system 401 as described above with respect to the deposition system 403.

Returning to FIG. 1, a controller 138 may be coupled to the parallel system 100 for controlling the operation thereof. The controller 138 generally comprises a central processing unit (CPU), a memory, and support circuits and is coupled to and controls the parallel system 100 and supporting systems (e.g., the gas injection system 108 and exhaust system 110), directly or, alternatively, via computers (or controllers) associated with each process chamber 104, 106 and/or the supporting systems. For example, the controller 138 may control the parallel system directly, or via computers (or controllers) associated with particular process chambers and/or the support system components.

The controller 138 may be one of any form of general-purpose computer processor that can be used in an industrial setting for controlling various chambers and sub-processors. The memory, or computer-readable medium, of the CPU may be one or more of readily available memory such as random access memory (RAM), read only memory (ROM), floppy disk, hard disk, flash, or any other form of digital storage, local or remote. The support circuits are coupled to the CPU for supporting the processor in a conventional manner. These circuits include cache, power supplies, clock circuits, input/output circuitry and subsystems, and the like. Inventive methods as described herein may be stored in the memory as a software routine that may be executed or invoked to control the operation of the parallel system 100 in the manner described herein. The software routine may also be stored and/or executed by a second CPU (not shown) that is remotely located from the hardware being controlled by the CPU of the controller 138.

Thus, embodiments of a parallel system for epitaxial deposition are provided herein. The parallel system described herein advantageously provides improved processing and process throughput for epitaxial growth processes at cost reduction through utilizing shared system resources (e.g., exhaust and gas injection systems) having independent control at each process chamber.

While the foregoing is directed to embodiments of the present invention, other and further embodiments of the invention may be devised without departing from the basic scope thereof.

1. A parallel system for epitaxial deposition, comprising:
a first body having a first process chamber and a second process chamber disposed within the first body;
a shared gas injection system coupled to each of the first and the second process chambers; and
a shared exhaust system coupled to each of the first and second process chambers, the exhaust system having independent control of an exhaust pressure from each chamber.

2. The system of claim 1, wherein the gas injection system provides independent control of the flow rate of a gas entering each process chamber.

3. The system of claim 1, wherein the first body further comprises a thermal epoxy surrounding the first and the second process chambers.

4. The system of claim 1, wherein each process chamber further comprises a chamber body formed of stainless steel tubing.

5. The system of claim 4, wherein an inner surface of each chamber body is lined with quartz.

6. The system of claim 1, wherein each process chamber further comprises a heating system to provide energy to an interior of each process chamber.

7. The system of claim 6, wherein each heating system is disposed only above each process chamber, or wherein each heating system is disposed only below each process chamber.

8. The system of claim 1, wherein the exhaust system further comprises:
an exhaust pump coupled to the first and second process chambers;
a first ballast system coupled to the first process chamber to independently control exhaust pressure from the first process chamber; and
a second ballast system coupled to the second process chamber to independently control exhaust pressure from the second process chamber.

9. The system of claim 8, further comprising:
a pressure control valve disposed between the exhaust pump and the first and second process chambers.

10. The system of claim 9, wherein the exhaust system further comprises:
a first isolation valve disposed between the first process chamber and the exhaust pump; and
a second isolation valve disposed between the second process chamber and the exhaust pump.

11. The system of claim 8, wherein the first ballast system further comprises:
a first ballast supply coupled to the first process chamber via a first mass flow controller to provide a ballast gas to adjust the pressure in the first process chamber; and
a first pressure transducer to monitor the pressure of the first chamber.

12. The system of claim 11, wherein the second ballast system further comprises:
a second ballast supply coupled to the second process chamber via a second mass flow controller to provide a ballast gas to adjust the pressure in the second process chamber; and
a second pressure transducer to monitor the pressure of the second chamber.

13. The system of claim 1, wherein the gas injection system further comprises:
a deposition system coupled to the first and second process chambers;
an etch system coupled to the first and second process chambers; and
a vent system coupled to the deposition system and the etch system to selectively vent gases from each of the etch and deposition systems.

14. The system of claim 13, wherein the deposition system further comprises:
a deposition manifold to provide a deposition gas;
a first deposition flow controller disposed between the deposition manifold and the first process chamber to independently control the flow rate of the deposition gas entering the first process chamber; and
a second deposition flow controller disposed between the deposition manifold and the second process chamber to independently control the flow rate of the deposition gas entering the second process chamber.

15. The system of claim 14, wherein the composition of a deposition gas supplied from the deposition manifold to each process chamber is fixed.

16. The system of claim 14, wherein the etch system further comprises:
a etch manifold to provide an etch gas;
a first etch flow controller disposed between the etch manifold and the first process chamber to independently control the flow rate of the etch gas entering the first process chamber; and
a second etch flow controller disposed between the etch manifold and the second process chamber to independently control the flow rate of the etch gas entering the second process chamber.

17. The system of claim 16, wherein the composition of an etch gas supplied from the etch manifold to each process chamber is fixed.

18. The system of claim 16, wherein the vent system further comprises:
a vent manifold to vent gases from the etch and deposition systems;
a first backpressure regulator disposed between the vent manifold and the deposition manifold to selectively permit gases from the deposition system to enter the vent system; and
a second backpressure regulator disposed between the vent manifold and the etch manifold to selectively permit gases from the etch system to enter the vent system.

19. The system of claim 16, further comprising:
an inlet assembly disposed within the first body, wherein the inlet assembly is coupled to the deposition system between the deposition manifold and the first and second deposition flow controllers and coupled to the etch system between the etch manifold and the first and second etch flow controllers.

20. The system of claim 19, wherein the inlet assembly further comprises:
a window to provide energy to a gas flowing through the inlet assembly prior to entering each process chamber.
